(19) United States
(12) Patent Application Publication
(10) Pub. No.: US 2004/0192022 A1
(43) Pub. Date: Sep. 30, 2004

(54) Semiconductor configuration with UV protection

(76) Inventors: Mirko Vogt, Dresden (DE); Veronika Polei, Bad Schandau (DE); Stephan Riedel, Dresden (DE); Elard Stein Von Kamienski, Dresden (DE)

Correspondence Address: LERNER AND GREENBERG, P.A., POST OFFICE BOX 2480, HOLLYWOOD, FL, 33022-2480, US

(21) Appl. No.: 10/611,066

(22) Filed: Jul. 1, 2003

(30) Foreign Application Priority Data
Jul. 1, 2002 (DE) 102 29 463.1

(51) Int. Cl. H01L 21/4763

(52) U.S. Cl. 438/622

(57) ABSTRACT

A semiconductor configuration has an active region, a metalization layer having at least one metal plane, and connecting lines between the active region and the metalization layer. The least one metal plane is embedded in an intermetal dielectric. A UV protection plane is integrated with the metalization layer. A method for fabricating such a semiconductor configuration is also provided.

### BACKGROUND OF THE INVENTION

1. Field of the Invention

The intention relates to a semiconductor configuration having an active region, a metalization layer including at least one metal plane, and connecting lines between the active region and the metalization layer, wherein the at least one metal plane is embedded in an intermetal dielectric.

In the production process of semiconductor configurations, ultraviolet rays are used in the exposure process for the patterning of the metal layers In addition, a plasma which emits UV (ultraviolet) radiation is produced during the application of further layers. The UV radiation leads to defects in the crystal structure of the semiconductor material. These defects cause undesired effects in the function of the semiconductor configurations Through the use of a heat treatment process, these defects are annealed at a temperature of approximately 450° C.

After the application of a first metal plane, however, the heat treatment process is unsuitable for annealing the disturbances in the crystal structure of the semiconductor configuration since the material of the metal plane can be destroyed by the high temperatures of the heat treatment process. This also applies to NROM (Nitrided Read Only Memory) cells.

The publication by B. Eitan et al.: “NROM: A Novel Localized Trapping, 2-Bit Nonvolatile Memory Cell” in IEEE Electron Device Letters, Vol. 21, No. 11, pages 543-545, November 2000, describes a memory cell in which doped regions are formed as source and drain in a semiconductor body or a semiconductor layer at a distance from one another. Situated on the top side of the semiconductor material is a word line, which functions as gate electrode above a channel region present between the source and drain regions. A storage layer including a layer sequence made of an oxide, a nitride and an oxide is situated, as gate dielectric and as storage medium, between the semiconductor material and the gate electrode. The storage layer is essentially limited to the channel region and regions of source and drain adjoining the latter. In order that, outside this region, too, the word line is electrically insulated from the doped regions of source and drain, regions made of an oxide, which may be fabricated e.g. by thermal oxidation of the semiconductor material, are respectively situated between the doped regions and the word line.

U.S. Pat. No. 6,133,095 describes a method for forming diffusion regions for source and drain in silicon, which can be used to fabricate a structure of a memory cell similar to that described in the publication by Eitan cited above. To that end, firstly the nitride layer of the storage layer is bombarded with ions using a suitable mask technique, which ions pass into the nitride layer only in those regions in which a thick oxide layer is to be fabricated as bit line oxide between source or drain, respectively, and the word line provided thereabove, so that the nitride layer becomes porous at these locations. Afterwards, both the porous silicon nitride layer and those portions of the silicon substrate which are present underneath are oxidized through the porous silicon nitride layer, thereby producing silicon oxynitride and silicon dioxide, respectively. The semiconductor material oxidized in this way forms thick oxide layers between the doped regions provided as source, drain and bit lines and the word line provided above.

This configuration of the memory cell has the disadvantage that the thickness of the bit line oxide has to be precisely controlled during fabrication. Moreover, during the thermal oxidation, the dopant diffuses out from the doped regions, something which has been compensated for hitherto by increasing the dimensions of the cell.

An NROM memory cell which can be fabricated in a simple manner, with smaller dimensions and smaller defect tolerances, is formed in planar fashion without additional oxidation for fabricating the bit line oxide The oxide-nitride-oxide layer provided as storage layer is provided on the semiconductor material with uniform thickness, so that this ONO layer forms not only the gate dielectric but also the insulation of the bit lines from the word lines or the gate electrode.

During the application of further layers, the process for fabricating such a planar NROM memory cell is accompanied by plasma processes in the same way as the fabrication of other semiconductor configurations. The plasma processes and the exposure process for forming the metal structures are the source of high-energy UV radiation. The UV radiation leads to a statistically uniform distribution of fixed charge carriers in the nitride of the ONO layer during the fabrication process.

The presence of such charge carriers leads to an undesired increase in the threshold voltage of a cell transistor of the NROM memory cells. In order to reduce the threshold voltage to a desired amount, the charge carriers have to be removed, or erased, from the nitride. Since the distribution of the charge carriers is provided statistically uniform over the entire nitride layer, a locally effective electrical erasure cannot be carried out. This can only be effected through a heat treatment of the NROM memory cell. The heat treatment is usually effected at temperatures which are incompatible for a metalization layer of the NROM memory cell. For this reason, the heat treatment must be effected before the metalization layer is applied. Consequently, it is not possible for electrons which are introduced into the nitride layer after the heat treatment to be removed from the nitride layer through the use of a further heat treatment process.

### SUMMARY OF THE INVENTION

It is accordingly an object of the invention to provide a semiconductor configuration which overcomes the above-mentioned disadvantages of the heretofore-known semiconductor configurations of this general type and which prevents, in a simple manner, the defects of the crystal structure of the semiconductor configuration which are caused by the UV radiation and/or the incorporation of fixed charge carriers during the further production process after the heat treatment. It is a further object of the invention to provide a method of manufacturing such a semiconductor configuration.

With the foregoing and other objects in view there is provided, in accordance with the invention, a semiconductor configuration, including:

an active region;

a metalization layer including at least one metal plane;

connecting lines extending between the active region and the metalization layer; and

an intermetal dielectric, the at least one metal plane being embedded in the intermetal dielectric; and

a UV protection plane integrated with the metalization layer.

In other words, the object of the invention is achieved by providing a semiconductor configuration having an active region, and also having a metalization layer including at least a first metal plane, and connecting lines between the active region and the metalization layer, the at least one metal plane being embedded in an intermetal dielectric, and a UV protection plane being integrated into the metalization layer.

If the UV protection plane according to the invention is formed from a metallic material, then its areal or planar configuration is adapted to the electrical properties of the, if appropriate, preceding or subsequently applied metal planes, so that the electrical properties of the latter are not influenced in an undesired manner. In this case, the UV protection plane including metal is introduced between the active region and the metalization layer, optionally also between two successive metal planes. In this case, the UV protection plane is embedded in an intermetal dielectric for the purpose of insulation from the subsequent metal planes.

An advantageous configuration of the invention provides the use of nonconducting and UV-opaque material for the UV protection plane. This has the advantage that there are no adaptations whatsoever in respect of the areal configuration, circuit design in the metal planes nor in the UV protection plane itself, since the latter, on account of its electrically insulating properties, does not influence the electrical properties of the metal planes.

Materials which are appropriate as a nonconducting and UV-opaque material are silicon oxynitride, silicon nitride and undoped silicon.

The use of nonconducting and UV-opaque material allows further advantageous embodiments. Thus, firstly, the UV protection plane is provided directly between the active region and the metalization layer. In a further advantageous embodiment, the intermetal dielectric situated between the respective metal planes is formed from such a nonconducting and UV-opaque material.

A further embodiment provides the UV-opaque and nonconducting UV protection plane as a plane between two adjacent metal planes.

With the objects of the invention in view there is also provided, a method for fabricating a semiconductor configuration, which includes the steps of:

fabricating an active region;

fabricating a metalization layer including at least one metal plane and connecting lines between the active region and the metalization layer such that the at least one metal plane is embedded in an intermetal dielectric; and

forming a UV protection plane integrated with the metalization layer.

According to another mode of the invention, the UV protection plane is formed prior to or during the step of forming the at least one metal plane.

According to yet another mode of the invention, the UV protection plane is formed from metal or a nonconducting and UV-opaque material.

According to a further mode of the invention, the UV protection plane is provided in the metalization layer or between the active region and the metalization layer.

In other words, according to the invention, there is provided, a method for fabricating a semiconductor configuration as defined above, wherein, before or during the application of the metal planes, a UV protection plane formed of metal or a nonconducting and UV-opaque material is introduced in front of or into the metalization layer.

According to a further feature of the invention, the at least one metal plane has electrical properties, and the UV protection plane is formed of metal as a planar configuration adapted to the electrical properties of the at least one metal plane.

According to yet a further feature of the invention, the active region is an active cell region, the UV protection plane is disposed between the active cell region and the metalization layer, and the UV protection plane is embedded in the intermetal dielectric.

According to another feature of the invention, the UV protection plane is disposed between the active region and the metalization layer.

According to a further feature of the invention, the intermetal dielectric is formed of a nonconducting and UV-opaque material.

According to a further feature of the invention, a first metal plane is embedded in the intermetal dielectric, a second metal plane is embedded in a further intermetal dielectric, and the intermetal dielectric and/or the further intermetal dielectric is formed of a nonconducting and UV-opaque material.

According to yet another feature of the invention, the UV protection plane is disposed between two adjacent metal planes.

Other features which are considered as characteristic for the invention are set forth in the appended claims.

Although the invention is illustrated and described herein as embodied in a semiconductor configuration and a fabrication method, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is a diagrammatic sectional view of a first embodiment of a semiconductor configuration according to the invention;

FIG. 2 is a diagrammatic sectional view of a second embodiment of a semiconductor configuration according to the invention;

FIG. 3 is a diagrammatic sectional view of a third embodiment of a semiconductor configuration according to the invention; and

FIG. 4 is a graph illustrating a test result for NROM memory cells protected from UV irradiation and unprotected NROM memory cells.

### DESCRIPTION OF THE PREFERRED EMBODIMENTS

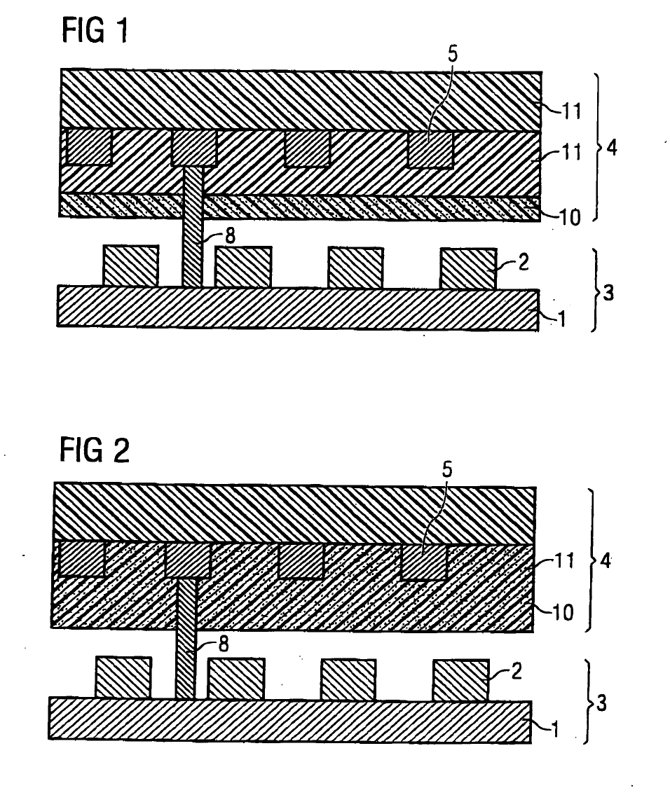

Referring now to the figures of the drawings in detail and first, particularly, to FIG. 1 thereof, there is shown a semiconductor configuration including an active region 3 and a metalization layer 4. In this case, the active region is divided into a bit line 1 and a word line 2 For its part, the metalization layer 4 is divided into at least one metal plane 5 and, if appropriate, further metal planes 5 which are provided in layers one above the other and are electrically isolated from one another by intermetal dielectrics 11 situated in between.

Connecting lines 8, so-called vias, are provided between the bit line 1 and the metal plane 5. In the production process, the semiconductor configuration is constructed from bottom to top, beginning with the active region. Thus, the completion of the active region 3 is followed by the process of heat treatment, during which the charge carriers fixed by UV radiation are erased, or removed from the storage layer.

In subsequent process steps, the semiconductor configuration is exposed to the high-energy UV radiation during the fabrication process. Therefore, it is advantageous to apply the UV protection plane in the subsequent production steps at the earliest possible point in time. The first embodiment illustrated in FIG. 1 and the second embodiment, which is illustrated in FIG. 2, represent the two embodiments in which the UV protection plane 10 is introduced as a first layer of the metalization layer 4.

In this case, the first embodiment illustrated in FIG. 1 differs from the second embodiment illustrated in FIG. 2 by the fact that a dedicated UV protection plane is embodied in the first embodiment illustrated in FIG. 1 and the UV protection plane 10 is embodied as an intermetal dielectric 11 in the second embodiment illustrated in FIG. 2.

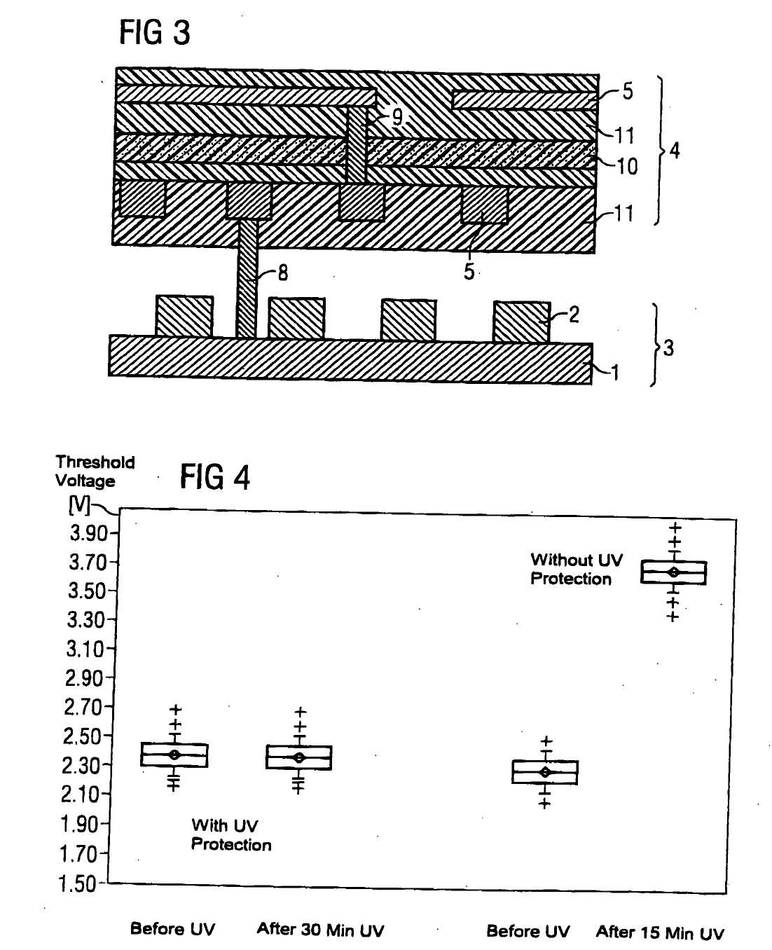

In the third embodiment illustrated in FIG. 3, the UV protection plane 10 is introduced between two adjacent metal planes 5.

Tests whose results are illustrated in FIG. 4 show the effectiveness of the embedded UV protection plane 10 in a direct comparison with NROM cells without a UV protection plane 10

After UV irradiation for approximately 15 minutes, the threshold voltage 12 of an unprotected NROM memory cell rises by approximately 1.4 volts, while an NROM memory cell 1 protected by a UV protection plane 10 according to the invention exhibits no rise in the threshold voltage even after UV irradiation for 30 minutes.

The application of the UV protection plane has been described above for the case of a fabrication of NROM memory cells. However, the invention is not limited to this exemplary embodiment. Rather, it is clearly evident that the basic concept of the invention can be applied to all process steps in semiconductor manufacturing in which UV irradiation leads to disadvantageous effects in the component.

We claim:

1. A semiconductor configuration, comprising:
an active region;
a metalization layer including at least one metal plane;
connecting lines extending between said active region and said metalization layer; and
an intermetal dielectric, said at least one metal plane being embedded in said intermetal dielectric; and
a UV protection plane integrated with said metalization layer.

2. The semiconductor configuration according to claim 1, wherein said at least one metal plane has electrical properties, and said UV protection plane is formed of metal as a planar configuration adapted to the electrical properties of said at least one metal plane.

3. The semiconductor configuration according to claim 2, wherein:
said active region is an active cell region;
said UV protection plane is disposed between said active cell region and said metalization layer; and
said UV protection plane is embedded in said intermetal dielectric

4. The semiconductor configuration according to claim 1, wherein said UV protection plane is formed of a nonconducting and UV-opaque material.

5. The semiconductor configuration according to claim 4, wherein said UV protection plane is formed of silicon oxynitride.

6. The semiconductor configuration according to claim 4, wherein said UV protection plane is formed of silicon nitride.

7. The semiconductor configuration according to claim 4, wherein said UV protection plane is formed of undoped silicon.

8. The semiconductor configuration according to claim 4, wherein said UV protection plane is disposed between said active region and said metalization layer.

9. The semiconductor configuration according to claim 1, wherein said intermetal dielectric is formed of a nonconducting and UV-opaque material,

10. The semiconductor configuration according to claim 1, wherein:
said at least one metal plane includes a first metal plane and a second metal plane;
said first metal plane is embedded in said intermetal dielectric, said second metal plane is embedded in a further intermetal dielectric; and
at least one of said intermetal dielectric and said further intermetal dielectric is formed of a nonconducting and UV-opaque material.

11. The semiconductor configuration according to claim 4, wherein:
said at least one metal plane includes two adjacent metal planes; and
said UV protection plane is disposed between said two adjacent metal planes.

12. A method for fabricating a semiconductor configuration, the method which comprises:
fabricating an active region;
fabricating a metalization layer including at least one metal plane and connecting lines between the active region and the metalization layer such that the at least one metal plane is embedded in an intermetal dielectric; and
forming a UV protection plane integrated with the metalization layer.

13. The method according to claim 12, which comprises forming the UV protection plane prior to forming the at least one metal plane.

14. The method according to claim 12, which comprises forming the UV protection plane during the step of forming the at least one metal plane.

15. The method according to claim 12, which comprises using a metal plane as the UV protection plane.

16. The method according to claim 12, which comprises forming the UV protection plane from a nonconducting and UV-opaque material.

17. The method according to claim 12, which comprises providing the UV protection plane in the metalization layer.

18. The method according to claim 12, which comprises providing the UV protection plane between the active region and the metalization layer.
